(19) United States
(12) Patent Application Publication
(10) Pub. No.: US 2025/0290992 A1
(43) Pub. Date: Sep. 18, 2025

(54) METHOD AND SYSTEM FOR DETECTING DEFECT OF BATTERY IN BATTERY FORMATION PROCESS

(71) Applicant: SK ON CO., LTD., Seoul (KR)

(72) Inventors: Woo Seop KIM, Daejeon (KR); Young Bee KIM, Daejeon (KR); Sang Jo MOON, Daejeon (KR); Joo Eun LEE, Daejeon (KR); Kyung Hee JEONG, Daejeon (KR); Seung Hoon JUNG, Daejeon (KR); Yu Jin JEONG, Daejeon (KR); Seon Hui CHOI, Daejeon (KR); Hyun Seong CHOI, Daejeon (KR)

(21) Appl. No.: 19/060,788

(22) Filed: Feb. 24, 2025

(30) Foreign Application Priority Data
Mar. 12, 2024 (KR) 10-2024-0034244
Nov. 4, 2024 (KR) 10-2024-0154154

(51) Int. Cl. G01R 31/385; G01R 19/12; G01R 19/165; G01R 31/3835; H01M 10/04; H01M 10/44

(52) U.S. Cl. CPC G01R 31/3865; G01R 19/12; G01R 19/16542; G01R 31/3835; H01M 10/0468; H01M 10/446

(57) ABSTRACT

A method for detecting a defect of a battery in a battery formation process according to an embodiment of the present disclosure, comprising: a measurement operation of pressurizing a battery cell and measuring a voltage of the battery cell under pressurization in the battery formation process; and an analysis operation of analyzing a difference between a pattern of the voltage and a reference pattern and detecting a defect in the battery cell based on an analysis result, wherein the analysis operation includes analyzing the difference between the pattern of the voltage and the reference pattern in a time range of less than 1 day and in a voltage range of less than 1 mV.

### CROSS-REFERENCE TO RELATED APPLICATION(S)

This application claims benefit of priorities to Korean Patent Application Nos. 10-2024-0034244 filed on Mar. 12, 2024 and 10-2024-0154154 filed on Nov. 4, 2024 in the Korean Intellectual Property Office, the disclosures of which are incorporated herein by reference in its entirety.

### BACKGROUND

### 1. Field

The present disclosure relates to a method and system for detecting a defect of a battery in a battery formation process.

### 2. Description of Related Art

In batteries, secondary batteries, unlike primary batteries, have the convenience of being able to charge and discharge electricity, and are thus receiving much attention as power sources for various mobile devices and electric vehicles. Such secondary batteries may include battery cells in which an electrode assembly is formed by stacking a positive electrode plate, a negative electrode plate, and a separator or by winding the same components in a roll shape and accommodating them inside a case. A plurality of battery cells may be stacked in a predetermined direction and accommodated in a battery module or a battery pack. A battery pack may include a plurality of battery modules.

Detecting defects in a battery during a battery manufacturing process is important in ensuring battery safety. The productivity of the battery manufacturing process can be improved as the efficiency of battery defect detection increases.

### SUMMARY

A method and system for detecting a defect of a battery in a battery formation process according to an embodiment of the present disclosure can efficiently detect a defect of a battery (e.g., a low voltage defect) in the battery formation process (e.g., not only shortening the time required for detecting a battery defect but also improving the performance of detecting a battery defect).

Since batteries can be used in eco-friendly electric vehicles, hybrid vehicles, etc. to prevent the effects of climate change by suppressing air pollution and greenhouse gas emissions, the method and system for detecting a defect of the battery in the battery formation process according to an embodiment of the present disclosure can also contribute to eco-friendly construction by reducing defects in shipped batteries (e.g., improving the speed of eco-friendly construction and/or preventing environmental pollution due to defects in shipped batteries).

According to an aspect of the present disclosure, a method for detecting a defect of a battery in a battery formation process is provided, including a measurement operation of pressurizing a battery cell and measuring a voltage of the battery cell under pressurization in the battery formation process; and an analysis operation of analyzing a difference between a pattern of the voltage and a reference pattern and detecting a defect in the battery cell based on an analysis result, wherein the analysis operation may include analyzing the difference between the pattern of the voltage and the reference pattern in a time range of less than 1 day and in a voltage range of less than 1 mV.

For example, the time range may be less than 1 hour and the voltage range may be less than 0.1 mV.

For example, the time range may be less than 20 seconds and the voltage range may be less than 0.05 mV.

For example, the time range may be from a point in time of pressurizing the battery cell to a point in time before the point in time of depressurizing the battery cell.

For example, the pressurization may include pressurizing the battery cell in the Press Pre-Charge (PPC) process.

For example, the method for detecting a defect of a battery in a battery formation process may further include a subsequent operation of performing at least one of an aging process to stabilize the battery cell and a degassing process to remove gas within the battery cell after the analysis operation.

For example, the method for detecting a defect of a battery in a battery formation process may further include an operation of manufacturing the battery cell by combining a battery case and battery electrodes and injecting an electrolyte into the battery case before the measurement operation.

For example, the measuring operation may further measure the voltage of the battery cell before pressurization, and the analyzing operation further includes analyzing a difference between a change pattern of a voltage before pressurization of the battery cell to a voltage during pressurization thereof and a change pattern of the reference.

For example, the analysis operation may include analyzing a difference between an average of the voltage during the time range and an average of the reference.

For example, the analysis operation may include analyzing the difference between a slope of the voltage from the point in time of pressurizing the battery cell to the point in time after a predetermined period of time has elapsed and a slope of the reference.

For example, the analysis operation may include generating information that the battery cell is defective when the absolute value of the slope of the voltage from the point in time of pressurization of the battery cell to the point in time after a predetermined period of time has elapsed is greater than the absolute value of the slope of the reference.

For example, the analysis operation may include analyzing whether the slope of the voltage from the point in time of pressurizing the battery cell to the point in time after a predetermined period of time has elapsed is positive or negative, and generating information that the battery cell is defective when the slope of the voltage is one of positive and negative, and generating information that the battery cell is normal when the slope of the voltage is the other of positive and negative.

According to another aspect of the present disclosure, a system for detecting a defect of a battery in a battery formation process is provided, including a pressurizer configured to pressurize a battery cell to be subjected to the battery formation process; a measuring device configured to measure a voltage of the battery cell during pressurization; and a controller configured to analyze a difference between a pattern of the voltage and a reference pattern and detect a defect in the battery cell based on an analysis result, wherein the controller may analyze a difference between the pattern of the voltage and the reference pattern in a time range of less than 1 day and in a voltage range of less than 1 mV.

For example, the time range may be less than 1 hour, the voltage range may be less than 0.1 mV, and the time range may be from the point in time of pressurization of the battery cell to a point in time before releasing pressurization of the battery cell.

For example, the time range may be less than 20 seconds, and the voltage range may be less than 0.05 mV.

For example, the pressurization may include pressurizing the battery cell in the Press Pre-Charge (PPC) process.

For example, the measuring device may further measure the voltage of the battery cell before pressurization, and the controller may further include analyzing a difference between a change pattern of a voltage before pressurization of the battery cell to a voltage during pressurization thereof and a change pattern of the reference.

For example, the controller may analyze the difference between an average of the voltage during the time range and an average of the reference, or may analyze the difference between a slope of the voltage from the point in time of pressurizing the battery cell to the point in time after a predetermined period of time has elapsed and a slope of the reference.

For example, the controller may include generating information that the battery cell is defective when an absolute value of the slope of the voltage from the point in time of pressurizing the battery cell to the point in time after a predetermined period of time has elapsed is greater than an absolute value of the slope of the reference.

For example, the controller may include analyzing whether the slope of the voltage from the point in time of pressurizing the battery cell to the point in time after a predetermined period of time has elapsed is positive or negative, and generating information that the battery cell is defective when the slope of the voltage is one of positive and negative, and generating information that the battery cell is normal when the slope of the voltage is the other of positive and negative.

In addition, the aspects of the present disclosure are not limited to the above-described aspects, and another aspect may be additionally understood in the process described below.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a flow chart illustrating battery processes containing a method and system for detecting a defect of a battery in a battery formation process according to an embodiment of the present disclosure;

FIG. 2A and FIG. 2B are flow charts illustrating a timing of detecting a defect in the method and system for detecting a defect of a battery in a battery formation process according to an embodiment of the present disclosure;

FIG. 3A to FIG. 3C are perspective views illustrating pressurizing and measuring a battery cell in the method and system for detecting a defect of a battery in a battery formation process according to an embodiment of the present disclosure;

FIG. 4 is a graph illustrating a rising pattern of voltage measured for a defective battery cell by the method and system for detecting a defect of a battery in a battery formation process according to an embodiment of the present disclosure, and a falling pattern of a reference; and

FIG. 5 is a graph illustrating a falling pattern of voltage measured for a defective battery cell by the method and system for detecting a defect of a battery in a battery formation process according to an embodiment of the present disclosure, and a rising pattern of a reference.

### DETAILED DESCRIPTION

Hereinafter, embodiments of the present disclosure will be further described with reference to specific experimental examples. Examples and comparative examples included in the experimental examples are merely illustrative of the present disclosure and do not limit the appended claims, and it is clear to those skilled in the art that various changes and modifications to embodiments can be made within the scope and technical idea of the present disclosure, and it is obvious that such modifications and modifications belong to the appended claims.

Various modifications may be made to the embodiments. Here, the embodiments should not be construed as being limited to the present disclosure and should be understood to include all changes, equivalents, and replacements within the idea and the technical scope of the disclosure.

The terms such as first, second, A, B, (a), (b), and the like may be used herein to describe components. Each of these terminologies is not used to define an essence, order or sequence of a corresponding component but used merely to distinguish the corresponding component from other component(s). For example, a first component may be referred to a second component, and similarly the second component may also be referred to as the first component. The term “and/or” may include combinations of a plurality of related described items or any of a plurality of related described items.

The terminology used herein is for the purpose of describing particular embodiments only and is not to be limiting of the embodiments. As used herein, the singular forms “a,” “an,” and “the” are intended to include the plural forms as well, unless the context clearly indicates otherwise. As used herein, the term “and/or” includes any one and any combination of any two or more of the associated listed items. It will be further understood that the terms “comprises” and/or “comprising,” when used in this disclosure, specify the presence of stated features, integers, operations, operations, elements, components or a combination thereof, but do not preclude the presence or addition of one or more other features, integers, operations, operations, elements, components, and/or groups thereof.

Unless otherwise defined herein, all terms used herein, including technical or scientific terms, have the same meanings as those generally understood by one of ordinary skill in the art. Terms defined in dictionaries generally used should be construed to have meanings matching contextual meanings in the related art and are not to be construed as having an ideal or excessively formal meaning, unless otherwise defined herein.

Hereinafter, an embodiment of the present disclosure will be described in more detail with reference to the accompanying drawings.

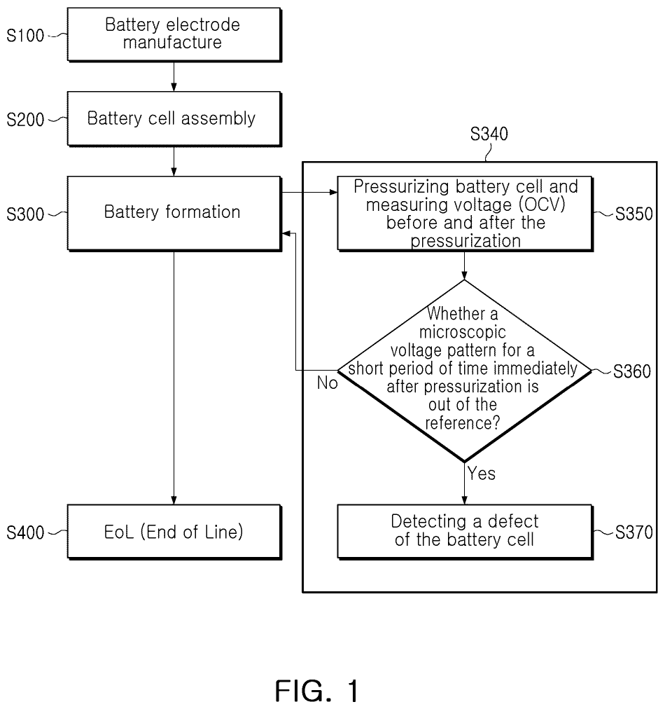

FIG. 1 is a flow chart illustrating battery processes containing a method and system for detecting a defect of a battery in a battery formation process according to an embodiment of the present disclosure.

Referring to FIG. 1, a battery formation process S300 of the method and system for detecting a defect of a battery in a battery formation process according to an embodiment of the present disclosure may be one of battery processes S100, S200, S300, S400 that are sequentially performed. The above battery processes may include an electrode manufacturing process S100, a battery cell assembly process S200, a battery formation process S300, and an EoL process S400. The End of Line (EoL) may be a battery post-process.

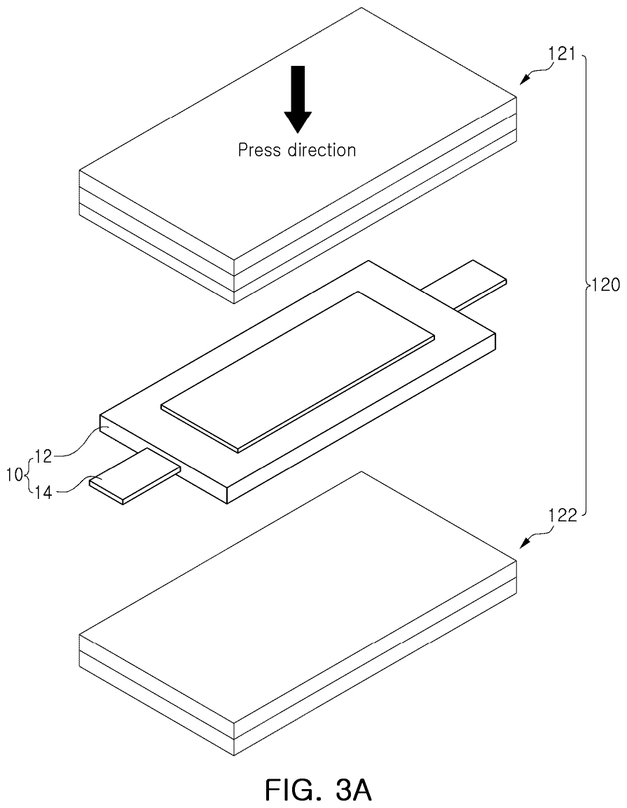

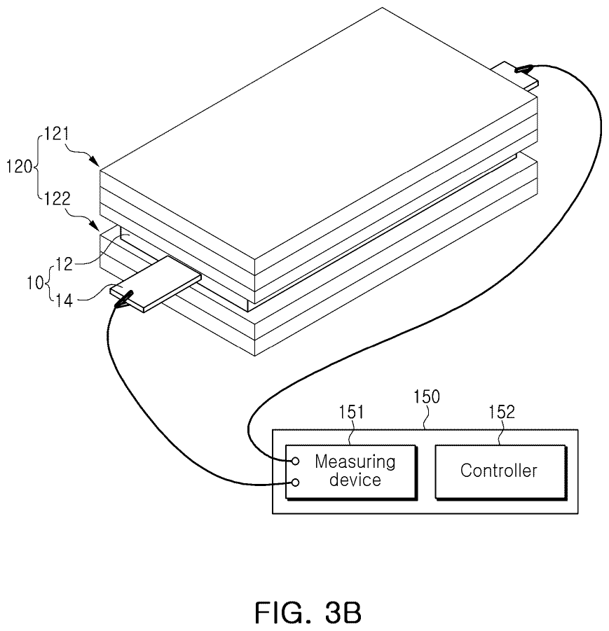

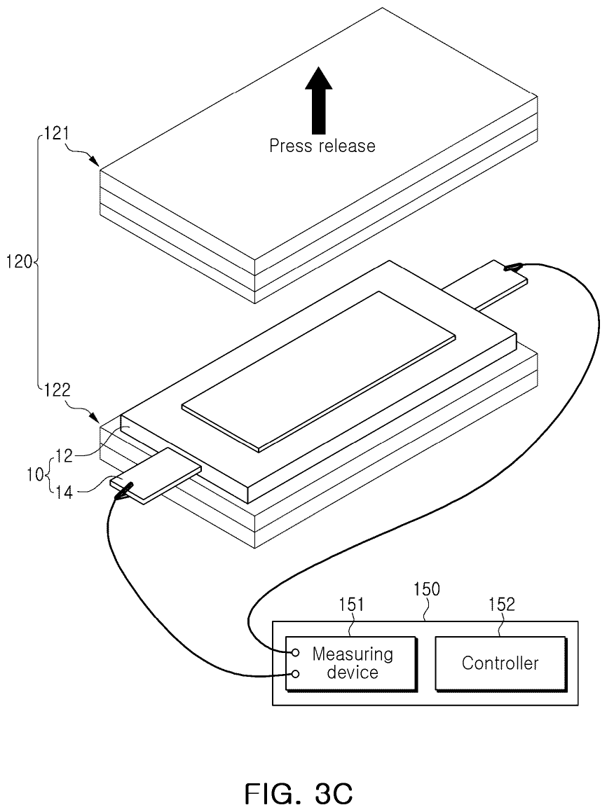

The electrode manufacturing process S100 may include an operation of manufacturing battery electrodes (14 of FIG. 3A) of at least one battery cell (10 of FIG. 3A). For example, the electrode manufacturing process S100 may include an operation of forming a slurry by mixing an active material, a conductive agent, a binder, and a solvent, an operation of coating the slurry on both sides of a positive electrode plate (e.g., an aluminum plate, a copper plate), an operation of rolling the coated positive electrode plate, an operation of forming electrodes by slitting the coated and rolled positive electrode plate, an operation of vacuum drying the electrodes, and an operation of notching the dried electrodes to manufacture the battery electrodes (e.g., electrode tabs).

Prior to the battery formation process S300 and the measuring operation S350, the battery cell assembly process S200 may include an operation of combining a battery case (12 of FIG. 3A) and battery electrodes (e.g., electrode tabs) and injecting an electrolyte into the battery case (12 of FIG. 3A) to manufacture a battery cell (10 of FIG. 3A) prior to the battery formation process S300, and may be included in the method for detecting a defect of a battery in a battery formation process according to an embodiment of the present disclosure.

For example, the battery cell assembly process S200 may include an operation of assembling tab-shaped battery electrodes (e.g., electrode tabs) and a separator (e.g., a porous polymer film or a porous non-woven fabric) according to a specific way (e.g., at least one of winding, stacking, Jelly Roll, Z-folding type, and stack-folding), an operation of welding the tab-shaped battery electrodes (e.g., electrode tabs) to connect positive electrodes or negative electrodes, and an operation of placing the welded battery electrodes (14 of FIG. 3A) in the battery case (12 of FIG. 3A) and injecting an electrolyte into the battery case (12 of FIG. 3A). The battery case (12 of FIG. 3A) may be a pouch-shaped case including a sealing portion, but may also be implemented as a cylindrical case or a prismatic case depending on the design.

The battery formation process S300 may include an operation of charging at least one battery cell (10 of FIG. 3A) so that the at least one battery cell (10 of FIG. 3A) assembled by the battery cell assembly process S200 has electrical characteristics. At this time, a solid electrolyte interphase layer may be formed on the negative electrode surface of the battery electrodes (e.g., electrode tabs), so that the at least one battery cell (10 of FIG. 3A) may have a microscopic structure capable of continuously performing an electrochemical reaction according to the voltage of the battery electrodes (e.g., electrode tabs).

For example, between the battery formation process S300 and the EoL process S400, a plurality of battery cells (10 of FIG. 3A) may be stacked and assembled into one battery module. For example, a plurality of battery modules may be assembled into one battery pack or one battery rack.

The EOL process S400 may include an inspection operation for at least one battery cell having electrical characteristics after the battery formation process S300. For example, the inspection may include at least one of an electrical performance (e.g., capacity, charge/discharge voltage/current, internal resistance, and insulation resistance) inspection of at least one battery cell, a temperature sensor performance inspection, a BMS (battery management system) performance inspection, and a battery cell appearance inspection. A battery on which the EoL process S400 is completed may be shipped for use in an eco-friendly vehicle such as an electric vehicle or for use in an energy storage system.

In general, in order to detect a defect (e.g., low voltage failure) of a battery cell, a voltage pattern of the battery cell resulting from leaving the battery cell for a long period (e.g., several days) in the battery formation process can be used. However, leaving the battery cell for such a long period (e.g., several days) can act as a limitation in reducing the total required period of the battery formation process and can cause a decrease in the overall productivity of battery processes.

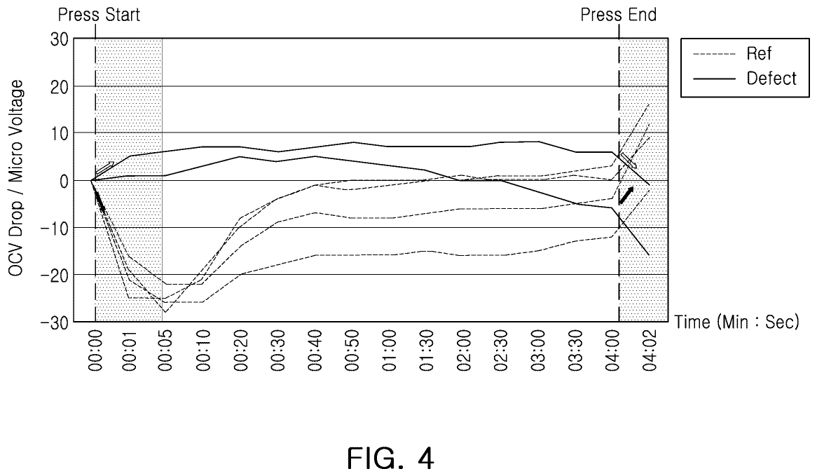

Referring to FIGS. 1 and 4, a method for detecting a defect of a battery in a battery formation process according to an embodiment of the present disclosure can perform an operation S340 of detecting a defect of a battery cell in the battery formation process S300, and a measuring operation S350 of pressurizing the battery cell (10 in FIG. 3A) in the battery formation process S300 and measuring the voltage (Open Circuit Voltage (OCV)) of the pressurized battery cell (10 in FIG. 3A) by a measuring device (151 in FIG. 3B); and analysis operations S360, S370 for analyzing (S360) a difference between a pattern of voltage (OCV) and a pattern of reference (Ref) by a controller (152 of FIG. 3B) and detecting (S370) a defect (e.g., low voltage failure) of the battery cell (10 of FIG. 3A) based on an analysis result.

In the battery formation process S300, the battery cell (10 of FIG. 3A) before voltage (OCV) stabilization may have a surface charge imbalance phenomenon. The surface charge imbalance phenomenon can be gradually resolved by leaving the battery cell for a long period of time (e.g., several days), but pressurizing the battery cell (10 of FIG. 3A) can resolve the surface charge imbalance phenomenon more quickly. That is, pressurizing the battery cell (10 of FIG. 3A) can promote voltage (OCV) stabilization of the battery cell (10 of FIG. 3A). Therefore, the total required time of operation S340 (e.g., less than 1 day) can be shortened, and the overall productivity of battery processes including the battery formation process S300 can be improved. That is, the above analysis operations S360, S370 can include analyzing the difference between the pattern of voltage (OCV) and the reference pattern (Ref) in a short time range of less than 1 day.

The horizontal axis of FIG. 4 represents time in units of minutes (Min) and seconds (Sec), and in a short time range of minutes (Min) and seconds (Sec) (e.g., 4 minutes in FIG. 4), the difference between the reference pattern (Ref) corresponding to the voltage pattern of a substantially non-defective battery cell and the voltage pattern (Defect) of a defective battery cell can be clearly analyzed. For example, the actual voltage at 0 minutes 0 seconds may be higher than 0 V, and the controller (152 in FIG. 3B) may adjust the actual voltage to a set voltage (e.g., 0 V) at 0 minutes 0 seconds in FIG. 4.

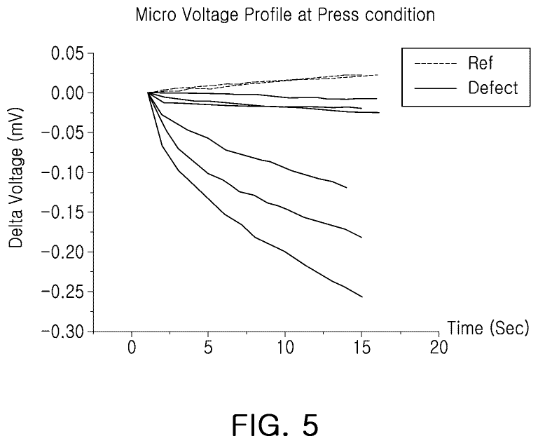

For example, FIG. 4 shows four reference patterns (Ref), and in the analysis operations S360, S370, the controller (152 in FIG. 3B) may integrate one pattern consisting of average values (each of the average values has a predetermined error range) at each point in time of four (two in FIG. 5) reference patterns (Ref), and by comparing the integrated reference pattern with the pattern of the measured voltage, a difference between the reference pattern and the measured pattern may be analyzed (e.g., determining whether the measured voltage is out of the error range of the reference).

For example, the reference pattern (Ref) can vary within a voltage range of −30 μV to +10 μV from a point in time of pressurization (Press Start) to a point in time of releasing pressurization (Press End), and the voltage pattern (Defect) of the defective battery cell can vary within a voltage range of +−10 μV from the point in time of pressurization (Press Start) to the point in time of releasing pressurization (Press End).

Depending on the chemical/physical composition of the battery cell (10 in FIG. 3A), internal resistance and equivalent circuit resistance components of the battery cell (10 in FIG. 3A) can vary. Therefore, a resistance behavior according to the pressurization of the battery cell (10 in FIG. 3A) can vary depending on the resistance component characteristics of the battery cell (10 in FIG. 3A).

For example, foreign matters or pinholes in the battery cell (10 in FIG. 3A) may be a low-voltage defect factor of the battery cell (10 in FIG. 3A) and may affect the movement distance of the electrolyte of the battery cell (10 in FIG. 3A) due to pressurization. For example, when a movement distance of the electrolyte of the battery cell (10 in FIG. 3A) due to pressurization decreases, the resistance behavior of the battery cell (10 in FIG. 3A) may change minutely at the mΩ level.

In general, since the voltage is analyzed in a large voltage range of mV or more in the battery formation process, it may be difficult to clearly analyze the difference between the reference pattern (Ref) and the voltage pattern of the defective battery cell (Defect) in the large voltage range, and the micro resistance behavior at the mΩ level (or microvoltage behavior at the μV level) may also be difficult to analyze.

However, the analysis operations S360, S370 may include analyzing the difference between the pattern of voltage (OCV) and the pattern of the reference (Ref) in a short time range of less than 1 day and in a microvoltage range of less than 1 mV, so that the micro resistance behavior at the level of mΩ (or microvoltage behavior at the level of μV) according to the pressurization can be analyzed, and the difference between the pattern of the reference (Ref) and the pattern of the voltage of the defective battery cell (Defect) in in a microvoltage range of less than 1 mV (in μV units) can be clearly analyzed. That is, the method for detecting a defect of a battery in a battery formation process according to an embodiment of the present disclosure can not only shorten the total required time of operation S340 (e.g., less than 1 day), but also improve the performance of detecting a defect in the battery cell in the operation S340.

The voltage range can be defined as the difference between the highest voltage and the lowest voltage during the time range. For example, the voltage range of the reference pattern (Ref) of FIG. 4 may be about 40 μV, and the voltage range of the pattern (Defect) of the voltage of the defective battery cell of FIG. 4 may be about 20 μV.

Since most of the changes in the chemical/physical composition (resistance behavior) of the battery cell (10 of FIG. 3A) due to pressurization may occur at the beginning of pressurization, the time range and the voltage range may be smaller depending on the design. For example, the time range may be less than 1 hour (e.g., in the unit of minutes (Min): seconds (Sec) of FIG. 4), and the voltage range may be less than 0.1 mV (e.g., in the range of +−30 μV of FIG. 4).

Depending on the type of defect in the battery cell (10 in FIG. 3A), the change in the chemical/physical composition (resistance behavior) of the battery cell (10 in FIG. 3A) due to pressurization may be revealed immediately after pressurization (e.g., for about 5 seconds from Press Start in FIG. 4) depending on whether the battery cell (10 in FIG. 3A) is defective. For example, the time range may be from the point in time of pressurization (Press Start in FIG. 4) of the battery cell (10 in FIG. 3A) to the point in time before the point in time of releasing pressurization (Press End in FIG. 4) of the battery cell (10 in FIG. 3A) (e.g., 5 seconds after Press Start in FIG. 4).

For example, the point in time at which the difference between the reference pattern (Ref) corresponding to the voltage pattern of a substantially non-defective battery cell and the voltage pattern (Defect) of the defective battery cell is the greatest may be about 10 seconds after the point in time of pressurization (Press Start of FIG. 4). For example, the time range may be 0.1 seconds or more and less than 20 seconds, and the voltage range may be less than 0.05 mV.

The analysis operations S360, S370 may include analyzing the difference between the average of the measured voltages during the time range and the average of the reference. For example, the average voltage difference between the voltage pattern (Defect) of the defective battery cell of FIG. 4 and the reference pattern (Ref) for 20 seconds from the point in time of pressurization (Press Start of FIG. 4) may be about 0.02 mV (5 μV+15 μV). At this time, since the difference in the average voltage exceeds an error range difference (e.g., 0.01 mV), the analysis operations S360, S370 may include generating information that the measured battery cell is defective. When the difference in the average voltage does not exceed the error range difference (e.g., 0.01 mV), the analysis operations S360, S370 may include generating information that the measured battery cell is normal.

The analysis operations S360, S370 may include analyzing the difference between the slope of the measured voltage from the point in time of pressurization of the battery cell 10 (Press Start in FIG. 4) to the point in time after a predetermined period of time (e.g., 5 seconds in FIG. 4) has elapsed and the slope of the reference. For example, the difference in slope between the voltage pattern (Defect) of the defective battery cell of FIG. 4 and the reference pattern (Ref) from the point in time of pressurization (Press Start of FIG. 4) for 5 seconds may be approximately 6 μV/sec (1 μV/sec+5 μV/sec). At this time, since the slope difference exceeds the error range difference (e.g., 3 μV/sec), the analysis operations S360, S370 may include generating information that the measured battery cell is defective. When the slope difference does not exceed the error range difference (e.g., 3 μV/sec), the analysis operations S360, S370 may include generating information that the measured battery cell is normal.

The analysis operations S360, S370 may include generating information that the battery cell (10 of FIG. 3A) is defective when an absolute value of the slope of the measured voltage from the point in time of pressurizing (Press Start of FIG. 4) of the battery cell to the point in time after a predetermined period of time (e.g., 5 seconds in FIG. 4) has elapsed is greater than an absolute value of the slope of the reference. For example, the difference in the absolute value of the slope of the voltage pattern (Defect) of the defective battery cell of FIG. 4 and the reference pattern (Ref) from the point in time of pressurization (Press Start of FIG. 4) for 5 seconds may be approximately 4 μV/sec (5 μV/sec-1 μV/sec). At this time, since the difference in the absolute values of the slopes exceeds an error range difference (e.g., 2 μV/sec), the analysis operations S360, S370 may include generating information that the measured battery cell is defective. When the difference in the absolute values of the above slopes does not exceed the error range difference (e.g., 2 μV/sec), the analysis operations S360, S370 may include generating information that the measured battery cell is normal.

The analysis operations S360, S370 may include analyzing whether the slope of the measured voltage from the point in time of pressurization (Press Start of FIG. 4) of the battery cell (10 of FIG. 3A) to the point in time after a predetermined period of time (e.g., 5 seconds in FIG. 4) has elapsed is positive or negative, and when the slope of the measured voltage is one of the positive and negative numbers (e.g., positive in FIG. 4), generating information that the battery cell (10 of FIG. 3A) is defective, and when the slope of the measured voltage is the other of the positive and negative numbers (e.g., negative in FIG. 4), generating information that the battery cell 10 is normal.

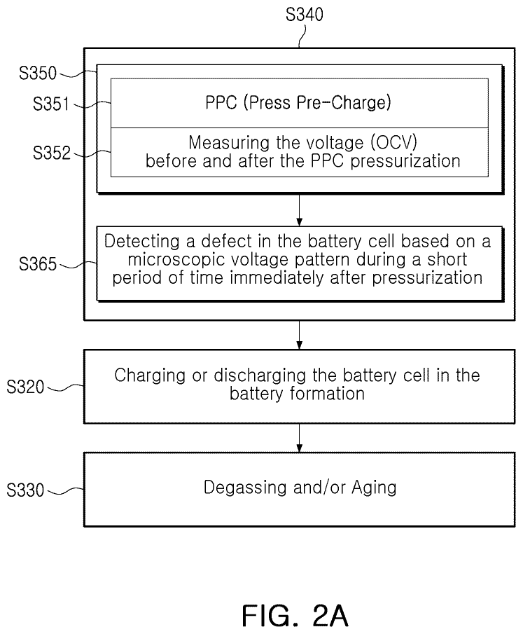

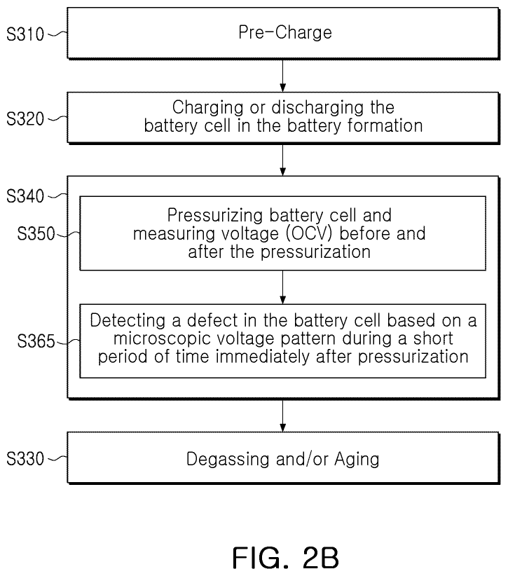

FIG. 2A and FIG. 2B are flow charts illustrating a timing of detecting a defect in the method and system for detecting a defect of a battery in a battery formation process according to an embodiment of the present disclosure.

Referring to FIG. 2A, the battery formation process S300 of FIG. 1 may include a Press Pre-Charge (PPC) operation S351 that simultaneously pressurizes and charges the battery cell (10 of FIG. 3A). Referring to FIG. 2B, the battery formation process S300 of FIG. 1 may include a pre-charge operation S310 in the battery cell (10 of FIG. 3A).

Referring to FIGS. 2A and 2B, the battery formation process S300 of FIG. 1 may include an operation S320 of performing formation charging or formation charging/discharging (charging and discharging) of the battery cell (10 of FIG. 3A), and a subsequent operation S330 of performing at least one of an aging process to stabilize the battery cell (10 of FIG. 3A) and a degassing process to remove gas (e.g., gas due to electrical characteristic formation) within the battery cell (10 of FIG. 3A).

The pressurization of the measurement operation S350 may include pressurizing the battery cell (10 of FIG. 3A) with the PPC, and may include an operation S352 of measuring the voltage before and after the PPC pressurization. The subsequent analysis operation S365 may include detecting defects in the battery cell based on microscopic (e.g., μV-scale) voltage patterns during a short period of time immediately after pressurization (e.g., less than 1 day, less than 1 hour, less than 20 seconds).

For example, the PPC operation S351 or the pre-charge operation S310 may include initially charging the battery cell (10 of FIG. 3A) by a predetermined capacity (e.g., 20%) after the battery cell (10 of FIG. 3A) is assembled. At this time, the inside of the battery cell (10 of FIG. 3A) may be gradually hardened. For example, the charger/discharger may charge the battery cell (10 of FIG. 3A) in a constant current mode, and the voltage of the battery cell (10 of FIG. 3A) may gradually increase as the charge proceeds. The pressurizer (120 of FIG. 3A) may be selectively used depending on the battery type, and may pressurize the battery cell (10 of FIG. 3A) to a predetermined pressure.

For example, the operation S320 of charging or discharging the battery cell (10 of FIG. 3A) in the battery formation may include charging the battery cell (10 of FIG. 3A) more than a predetermined capacity (e.g., 20%), and, depending on the design, may further include discharging the battery cell (10 of FIG. 3A) to a predetermined capacity (e.g., 20%). For example, when the battery cell (10 of FIG. 3A) is pressurized in the PPC operation S351 or the pre-charging operation S310, the operation S320 may include charging or discharging the battery cell (10 of FIG. 3A) after releasing the pressurization. Depending on the design, aging and/or degassing may be included between the PPC operation S351 or the pre-charge operation S310 and the operation S320. In this case, the operation S320 may also be defined as a shipping charge.

Referring to FIGS. 3A to 3C, a system 150 for detecting a defect of a battery in a battery formation process according to an embodiment of the present disclosure may include a pressurizer 120 configured to pressurize a battery cell 10 to undergo the battery formation process, a measuring device 151 configured to measure a voltage of the battery cell 10 under pressurization, and a controller 152 configured to analyze a difference between the pattern of the measured voltage (e.g., the pattern of the voltage of the defective battery cell (Defect)) and a reference pattern (Ref) and detect the defect (e.g., a low voltage defect) of the battery cell 10 based on an analysis result. The controller 152 can analyze the difference between the pattern of the measured voltage and the reference pattern in a short time range of less than 1 day and in a microvoltage range of less than 1 mV. Accordingly, the system 150 for detecting a defect of a battery in a battery formation process can not only shorten the time required for battery defect detection, but also improve the battery defect detection performance.

For example, the battery cell 10 can be formed by housing an electrode assembly composed of a positive electrode plate, a negative electrode plate, and a separator in an outer material, injecting an electrolyte into the outer material, and then sealing the outer material. At this time, the electrodes 14 (e.g., electrode tabs) respectively connected to the positive electrode plate and the negative electrode plate can be in a form exposed to the outside of the outer material.

FIG. 3A to FIG. 3C are perspective views illustrating pressurizing and measuring a battery cell in the method and system for detecting a defect of a battery in a battery formation process according to an embodiment of the present disclosure.

FIG. 3A corresponds to before the point in time of pressurization (Press Start of FIG. 4), FIG. 3B corresponds to from the point in time of pressurization (Press Start of FIG. 4) to the pressurizing release point (Press End of FIG. 4), and FIG. 3C corresponds to after the point in time of releasing pressurization (Press End of FIG. 4).

For example, the pressurizer 120 may include a plurality of support plates 121, 122. Referring to FIG. 3A, the battery cell 10 may be placed between the plurality of support plates 121, 122. Referring to FIG. 3B, the plurality of support plates 121, 122 may be brought closer to each other to press the battery cell 10 in the vertical direction. At this time, the measuring device 151 may be electrically connected to the electrode 14 (e.g., electrode tabs) to measure the voltage (OCV) of the battery cell 10. Referring to FIG. 3C, the plurality of support plates 121, 122 can be moved apart from each other to release the compression on the battery cell 10.

For example, each of the plurality of support plates 121, 122 can be implemented in a polyhedral shape having a flat surface (upper surface and/or lower surface) facing the battery cell 10, and can compress the battery cell 10 by receiving a force controlled by the controller 152 in the upper and lower direction. Depending on the design, the plurality of support plates 121, 122 can be implemented to move only in the upper and lower direction while preventing horizontal movement through fastening means such as bolts and screws. Depending on the design, the pressurizer 120 may be implemented as a roller instead of a plurality of support plates 121, 122, and may press the battery cell 10 by rolling the roller on at least one of sides of the battery cell 10.

For example, the pressure at which the pressurizer 120 presses the battery cell 10 may be 0.1 MPa or more and 10 MPa or less (an error range is +−50 kN/mm²), and may be non-destructively set so that there is no actual performance reduction or damage to the battery cell 10. The temperature before and after the pressure of the pressurizer 120 may be room temperature (18 degrees Celsius to 28 degrees Celsius), and may decrease to −10 degrees Celsius or increase to 60 degrees Celsius depending on the design, but is not limited thereto.

For example, the measuring device 151 may be implemented as a digital multimeter and may include an analog measuring circuit (e.g., a sampling circuit, a buffer circuit, an amplifier circuit, an analog-to-digital conversion circuit).

For example, the measuring device 151 may include a sampling circuit that repeatedly samples the voltage of the battery cell 10 at short intervals, an envelope detection circuit that detects the trend of the voltage of the battery cell 10 by frequency analysis (or Fourier transform-based analysis), and a timer (which may be included in the controller 152) that counts time and generates a time value.

For example, the measuring device 151 may assign a time value to each of the sampled voltages, and may determine whether the voltage of the battery cell is rising or falling based on the difference between the time values between adjacent sampled voltages, and may also calculate the rising/falling speeds (or slopes). Depending on the design, the measuring device 151 may make the judgment and/or calculation based only on the sampling voltage of a time value falling within a predetermined period of time range among the time values of the sampling voltage.

For example, the controller 152 may be implemented as a data acquisition system and may include a computing system (e.g., a microcontroller, a programmable logic controller (PLC), an embedded system, a manufacturing execution system (MES)). For example, the computing system may include a processor (e.g., a CPU, a GPU), a memory (e.g., a volatile memory, a nonvolatile memory), a recording medium, an input/output device, and a communication device. For example, the controller 152 may operate in a manner in which the processor executes one or more programs (and/or algorithms, logic) recorded in the memory or storage, and the operation may correspond to the instructions of the program and may correspond to the operation executed by the method for detecting a defect of a battery in a battery formation process according to an embodiment of the present disclosure. For example, the controller 152 may store the reference pattern (Ref) of FIG. 4 in the memory and analyze the pattern through the processor.

The horizontal axis of FIG. 5 represents time in seconds (Sec), and in a short time range in seconds (e.g., 15 seconds), the difference between the reference pattern (Ref) corresponding to a voltage pattern of a substantially non-defective battery cell and the voltage pattern (Defect) of a defective battery cell can be clearly analyzed. For example, the actual voltage at 0 seconds can be higher than 0 V, and the controller 152 can adjust the actual voltage to the set voltage (e.g., 0 V) of 0 seconds of FIG. 5.

According to the design, the measurement operation (S350 in FIG. 1) may further measure the voltage of the battery cell (10 in FIG. 3A) before (e.g., 0 seconds in FIG. 5) the point in time of pressurization (e.g., 1 second in FIG. 5), and the analysis operations (S360, S370 in FIG. 1) may further include analyzing the difference between the change pattern of the voltage of the battery cell (10 in FIG. 3A) before pressurization (e.g., 0 V) to the voltage during pressurization and the change pattern of the reference. Accordingly, an unintended slight mismatch between the point in time of pressurization and the point in time of starting the set measurement can be prevented from reducing the analysis accuracy.

For example, from the point in time of pressurization (e.g., 1 second) to the point in time after a predetermined period of time (e.g., 14 seconds) has elapsed, the reference pattern (Ref) may rise within a voltage range from 0 V to 0.025 mV, a part of the pattern (Defect) of the voltage of the defective battery cell (the first defect type) may fall gently within a voltage range from 0 V to −0.02 mV, and the remainder of the pattern (Defect) of the voltage of the defective battery cell (the second defect type) may fall steeply within a voltage range from 0 V to about −0.2 mV (a voltage range of less than 1 mV).

The reference pattern (Ref) and the pattern (Defect) of the voltage of the defective battery cell may be different from each other in FIGS. 4 and 5. This may be due to the fact that the battery cells of FIG. 4 and FIG. 5 are different models (models, types), and the resistance behavior (internal resistance and equivalent circuit resistance components) according to pressurization may also be different between FIGS. 4 and 5.

For example, different models (models, types) may mean different shapes (e.g., pouch type, prismatic type, cylindrical type) or different materials (e.g., LFP (lithium iron phosphate), NCM (LiNiMnCoO2), mid-Ni, high-Ni).

According to the aspects of the present disclosure, a defect of a battery (e.g., a low voltage defect) in the battery formation process (e.g., not only shortening the time required for detecting a battery defect but also improving the performance of detecting a battery defect) can be efficiently detected.

For example, the process of leaving a battery cell for a long period of time (e.g., several days) in a battery formation process can be omitted in order to detect a defect of a battery cell (e.g., a low voltage defect) in the battery formation process.

While example embodiments have been illustrated and described above, it will be apparent to those skilled in the art that modifications and variations could be made without departing from the scope of the present disclosure as defined by the appended claims.

What is claimed is:

1. A method for detecting a defect of a battery in a battery formation process, comprising:
a measurement operation of pressurizing a battery cell and measuring a voltage of the battery cell under pressurization in the battery formation process; and
an analysis operation of analyzing a difference between a pattern of the voltage and a reference pattern and detecting a defect in the battery cell based on an analysis result,
wherein the analysis operation includes analyzing the difference between the pattern of the voltage and the reference pattern in a time range of less than 1 day and in a voltage range of less than 1 mV.

2. The method of claim 1, wherein the time range is less than 1 hour, and
the voltage range is less than 0.1 mV.

3. The method of claim 1, wherein the time range is less than 20 seconds, and
the voltage range is less than 0.05 mV.

4. The method of claim 1, wherein the time range is from a point in time of pressurizing the battery cell to a point in time before a point in time of depressurizing the battery cell.

5. The method of claim 1, wherein the pressurization includes pressurizing the battery cell in the Press Pre-Charge (PPC) process.

6. The method of claim 1, further comprising a subsequent operation of performing at least one of an aging process to stabilize the battery cell and a degassing process to remove gas within the battery cell after the analysis operation.

7. The method of claim 1, further comprising an operation of manufacturing the battery cell by combining a battery case and battery electrodes and injecting an electrolyte into the battery case before the measurement operation.

8. The method of claim 1, wherein the measuring operation further measures the voltage of the battery cell before pressurization, and
the analyzing operation further includes analyzing a difference between a change pattern of a voltage before pressurization of the battery cell to a voltage during pressurization of the battery cell and a change pattern of the reference.

9. The method of claim 1, wherein the analysis operation includes analyzing a difference between an average of the voltage during the time range and an average of the reference.

10. The method of claim 1, wherein the analysis operation includes analyzing the difference between a slope of the voltage from a point in time of pressurizing the battery cell to a point in time after a predetermined period of time has elapsed and a slope of the reference.

11. The method of claim 10, wherein the analysis operation includes generating information that the battery cell is defective when an absolute value of the slope of the voltage from the point in time of pressurizing the battery cell to the point in time after a predetermined period of time has elapsed is greater than an absolute value of the slope of the reference.

12. The method of claim 10, wherein the analysis operation includes analyzing whether the slope of the voltage from the point in time of pressurizing the battery cell to the point in time after a predetermined period of time has elapsed is positive or negative, and generating information that the battery cell is defective when the slope of the voltage is one of positive and negative, and generating information that the battery cell is normal when the slope of the voltage is the other of positive and negative.

13. A system for detecting a defect of a battery in a battery formation process, comprising:
a pressurizer configured to pressurize a battery cell to be subjected to the battery formation process;
a measuring device configured to measure a voltage of the battery cell during pressurization; and
a controller configured to analyze a difference between a pattern of the voltage and a reference pattern and detect a defect in the battery cell based on an analysis result,
wherein the controller analyzes a difference between the pattern of the voltage and the reference pattern in a time range of less than 1 day and in a voltage range of less than 1 mV.

14. The system of claim 13, wherein the time range is less than 1 hour,
the voltage range is less than 0.1 mV, and
the time range is from a point in time of pressurization of the battery cell to a point in time before a point in time of releasing pressurization of the battery cell.

15. The system of claim 14, wherein the time range is less than 20 seconds, and
the voltage range is less than 0.05 mV.

16. The system of claim 13, wherein the pressurization includes pressurizing the battery cell in the Press Pre-Charge (PPC) process.

17. The system of claim 13, wherein the measuring device further measures the voltage of the battery cell before pressurization, and
the controller further includes analyzing a difference between a change pattern of a voltage before pressurization of the battery cell to a voltage during pressurization of the battery cell and a change pattern of the reference.

18. The system of claim 13, wherein the controller analyzes the difference between an average of the voltage during the time range and an average of the reference, or
analyzes the difference between a slope of the voltage from a point in time of pressurizing the battery cell to a point in time after a predetermined period of time has elapsed and a slope of the reference.

19. The system of claim 18, wherein the controller includes generating information that the battery cell is defective when an absolute value of the slope of the voltage from the point in time of pressurizing the battery cell to the point in time after a predetermined period of time has elapsed is greater than an absolute value of the slope of the reference.

20. The system of claim 18, wherein the controller includes analyzing whether the slope of the voltage from the point in time of pressurizing the battery cell to the point in time after a predetermined period of time has elapsed is positive or negative, and generating information that the battery cell is defective when the slope of the voltage is one of positive and negative, and generating information that the battery cell is normal when the slope of the voltage is the other of positive and negative.
